(19) United States
(12) Patent Application Publication
(10) Pub. No.: US 2016/0093556 A1
(43) Pub. Date: Mar. 31, 2016

(54) QUAD-FLAT NON-LEAD PACKAGE STRUCTURE AND METHOD OF PACKAGING THE SAME

(71) Applicant: LINGSEN PRECISION INDUSTRIES, LTD., Taichung City (TW)

(72) Inventors: Ming-Te TU, Taichung City (TW); Ching-I LIN, Taichung City (TW); Chia-Jen HSU, Taichung City (TW); Sheng-Jen LIN, Taichung City (TW)

(21) Appl. No.: 14/535,766

(22) Filed: Nov. 7, 2014

(30) Foreign Application Priority Data
Sep. 30, 2014 (TW) 103133940

(51) Int. Cl. H01L 23/495; H01L 21/56; H01L 21/48; H01L 23/31; H01L 23/00

(52) U.S. Cl. CPC H01L 23/4952; H01L 23/3114; H01L 23/49503; H01L 23/49541; H01L 24/73; H01L 24/32; H01L 24/49; H01L 24/92; H01L 24/83; H01L 24/85; H01L 21/4825; H01L 21/4842; H01L 21/565; H01L 2224/32245; H01L 2224/48106; H01L 2224/48247; H01L 2224/73265; H01L 2224/838; H01L 2224/92247

(57) ABSTRACT

A quad-flat non-lead package structure includes a film layer, a conducting layer, a die, an encapsulant, and a plurality of metal bumps. The film layer has a plurality of through holes. A pad of the conducting layer and conducting wirings are disposed at the film layer but are not connected to each other. The conducting wirings are disposed at the through holes, respectively. The die is fixedly disposed at the pad and electrically connected to the conducting wirings. The encapsulant covers the conducting layer and the die. The metal bumps are disposed in the through holes, respectively, each have one end electrically connected to a corresponding one of the conducting wirings, and each have the other end protruding from a corresponding one of the through holes. Accordingly, the quad-flat non-lead package structure features reduced likelihood of pin disconnection and enhanced adhesiveness required for surface-mount technology.

### BACKGROUND OF THE INVENTION

1. Field of the Invention

The present invention relates to package structures and methods of packaging the same, and more particularly, to a quad-flat non-lead package structure and a method of packaging the same.

2. Description of Related Art

Given ever-changing technologies, high-tech electronic manufacturers rapidly roll out various electronic products which feature a high degree of versatility and personalization and thus bring about rapid development of semiconductor packages in terms of miniaturization, such as a quad-flat non-lead package (QFN) and a wafer-level chip-scale package (WLCSP), with a view to reducing component volume, cutting production costs effectively, and achieving enhanced electrical characteristics.

A conventional QFN packaging method involves mounting a die on a lead frame by a die attach process, connecting a plurality of wires electrically to the lead frame, and forming an encapsulant for covering the lead frame, a chip, and the wires, so as to finalize the manufacturing of a QFN package structure.

### BRIEF SUMMARY OF THE INVENTION

It is an objective of the present invention to provide a quad-flat non-lead package structure and a method of packaging the same so as to prevent pin disconnection and enhance adhesiveness required for surface mount technology.

In order to achieve the above and other objectives, the present invention provides a method of packaging a quad-flat non-lead package structure, comprising the steps of:
providing a film layer;
providing a conducting layer on the film layer;
forming a pad and a plurality of conducting wirings on the conducting layer by a means of circuit layout, wherein the conducting wirings are positioned proximate to the pad but are not connected to each other;
providing a die, followed by disposing the die at the pad by a means of fixing;
connecting the die electrically to the conducting wirings by a means of electrical connection;
forming an encapsulant for covering the die and the conducting wirings;
forming a plurality of through holes in the film layer by a means of drilling, such that the conducting wirings are exposed from the through holes, respectively; and
providing a plurality of metal bumps in the through holes, respectively, in a manner to connect the metal bumps electrically to the conducting wirings, respectively;
wherein the method further comprises laying an adhesive of high adhesiveness on the film layer to adhere the conducting layer thereto;
wherein the means of fixing is a die attach process;
wherein the means of electrical connection is a wire bonding process;
wherein the means of drilling is a laser drilling process; and
wherein the encapsulant is formed by molding.

In order to achieve the above and other objectives, the present invention further provides a quad-flat non-lead package structure, comprising a film layer, a conducting layer, a die, an encapsulant, and a plurality of metal bumps, wherein the film layer has a plurality of through holes, the conducting layer is disposed at the film layer and has a pad and a plurality of conducting wirings, wherein the pad is not connected to the conducting wirings, wherein the conducting wirings are disposed in the through holes, respectively, wherein the die is fixedly disposed at the pad and electrically connected to the conducting wirings, wherein the encapsulant covers the conducting layer and the die, wherein the metal bumps are disposed in the through holes, respectively, wherein the metal bumps each have one end electrically connected to a corresponding one of the conducting wirings and the other end protruding from a corresponding one of the through holes.

The quad-flat non-lead package structure further comprises at least a wire for electrically connecting the die and the conducting wirings.

The film layer has an adhesive. The adhesive adheres the pad and the conducting wirings in place.

Therefore, according to the present invention, a quad-flat non-lead package structure and a method of packaging the same are conducive to preventing pin disconnection and enhancing the adhesiveness required for surface-mount technology.

To enable examiners further understand the structure, features, and objectives of the present invention, the present invention is illustrated with embodiments and drawings and described hereunder so that persons skilled in the art can implement the present invention accordingly. However, the description below is merely intended to provide the embodiments for explaining the technical contents and features of the present invention. After understanding the technical contents and features of the present invention, persons skilled in the art can carry out all kinds of modifications, replacements, and reduction of constituent components to the present invention without departing from the spirit of the present invention, and the modifications, replacements, and reduction of constituent components are deemed falling within the claims of the present invention.

### BRIEF DESCRIPTION OF THE SEVERAL VIEWS OF THE DRAWINGS

Objectives, features, and advantages of the present invention are hereunder illustrated with specific embodiments in conjunction with the accompanying drawings, in which:

FIG. 1 is a schematic view of a quad-flat non-lead package structure of the present invention; and

FIG. 2a through FIG. 2g are a flowchart of a method of packaging a quad-flat non-lead package structure according to the present invention.

### DETAILED DESCRIPTION OF THE INVENTION

To enable persons skilled in the art to fully understand the structures, features, and advantages of the present invention, the present invention is hereunder illustrated with a preferred embodiment in conjunction with the accompanying drawings.

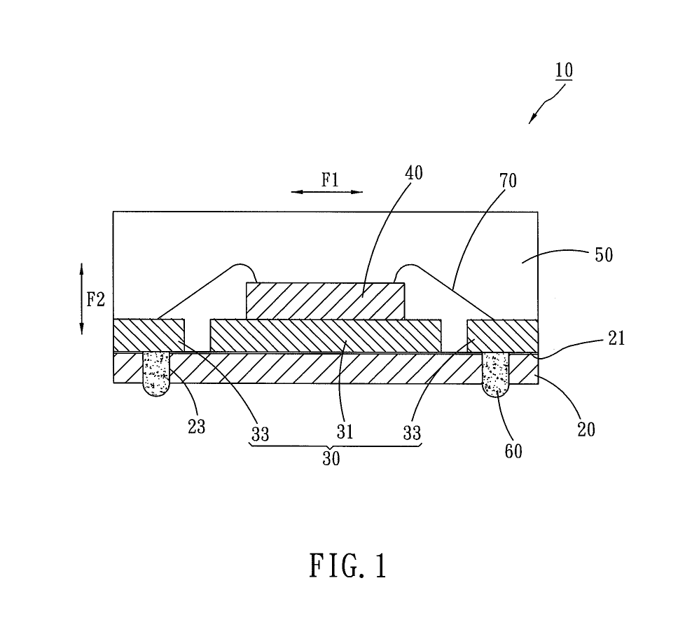

Referring to FIG. 1, the present invention provides a quad-flat non-lead package structure 10 which comprises a film layer 20, a conducting layer 30, a die 40, an encapsulant 50, and a plurality of metal bumps 60.

The film layer 20 has an adhesive 21 and has a plurality of through holes 23 penetrating the film layer 20 and the adhesive 21. In the preferred embodiment of the present invention, the film layer 20 is either an adhesive tape or a film with one side thereof having a glue.

The conducting layer 30 is not only disposed at the film layer 20 but also has a pad 31 and a plurality of conducting wirings 33. The pad 31 is not connected to the conducting wirings 33. The conducting wirings 33 are disposed at the through holes 23, respectively. In the preferred embodiment of the present invention, the pad 31 and the conducting wirings 33 are provided in the form of copper foil. The pad 31 is adhered to the adhesive 21. A major portion of each conducting wiring 33 is adhered to the adhesive 21. A minor portion of each conducting wiring 33 is disposed at a corresponding one of the through holes 23 but is not adhered to the adhesive 21.

The die 40 is fixedly disposed at the pad 31. The die 40 is electrically connected to the conducting wirings 33 through a wire 70. In the preferred embodiment of the present invention, the quantity of the wire 70 is not restricted to one but can be increased as needed. Referring to FIG. 1, for example, the wire 70 is in the number of two, and the two wires 70 are electrically connected to two conducting wirings 33, respectively.

The encapsulant 50 covers the conducting layer 30 and the die 40 to protect the die 40, the conducting wirings 33, and the wires 70.

The metal bumps 60 are disposed in the through holes 23, respectively. The metal bumps 60 each have one end electrically connected to a corresponding one of the conducting wirings 33 and the other end protruding from a corresponding one of the through holes 23. Hence, signals from the die 40 are not only sent to the conducting wirings 33 through the wires 70 but also sent out through the metal bumps 60 electrically connected to the conducting wirings 33. Furthermore, transverse acting force F1 exerted by the metal bumps 60 is restrained by the through holes 23 of the film layer 20, whereas longitudinal acting force F2 exerted by the metal bumps 60 is restrained by the conducting wirings 33; hence, even though various forces are applied to the quad-flat non-lead package structure 10 of the present invention, the metal bumps 60 are steadily and firmly fixed to the conducting wirings 33, thereby preventing pin disconnection and enhancing the adhesiveness required for surface-mount technology.

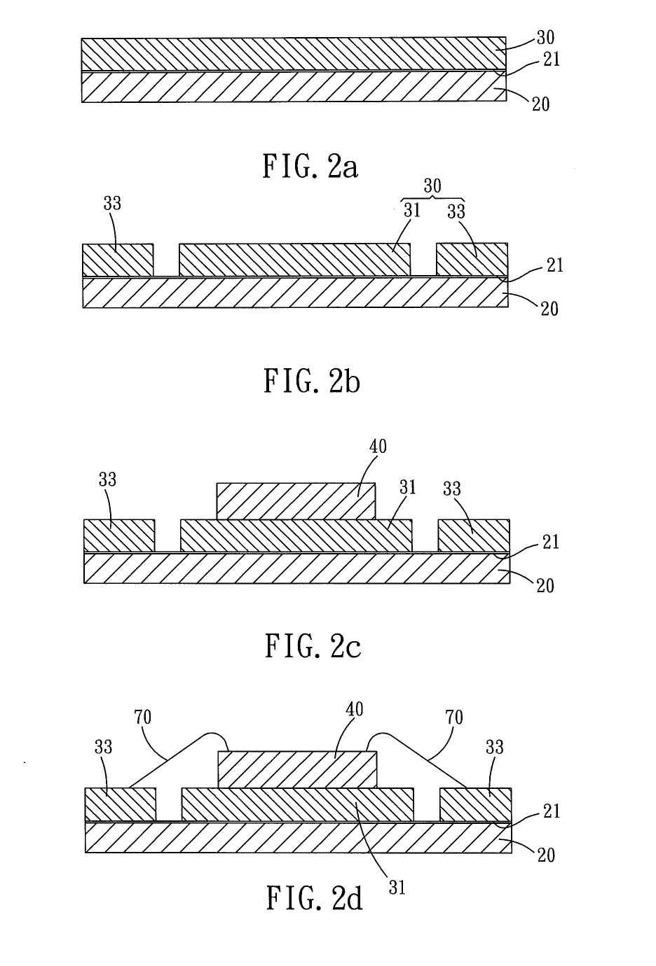

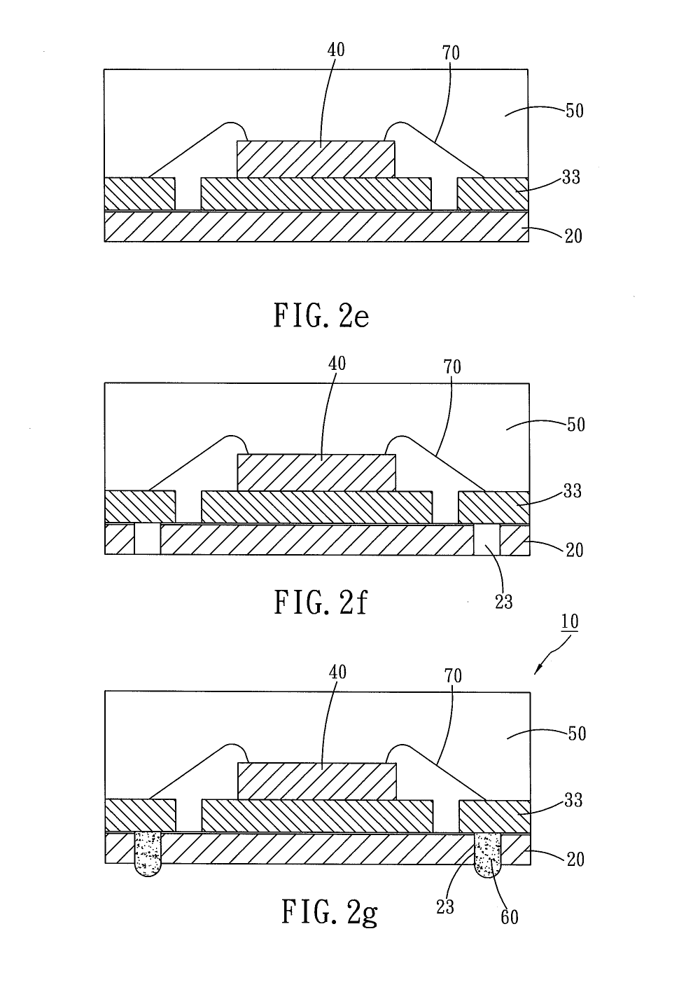

Referring to FIG. 2, in the preferred embodiment of the present invention, a method of packaging a quad-flat non-lead package structure comprises the steps below.

Step A: forming the conducting layer 30 on the film layer 20, as shown in FIG. 2a. In the preferred embodiment of the present invention, the film layer 20 is coated with an adhesive 21 of high adhesiveness to allow the conducting layer 30 to be easily and firmly adhered to the film layer 20.

Step B: forming the pad 31 and the conducting wirings 33 on the conducting layer 30 by a means of circuit layout, wherein the conducting wirings 33 are positioned proximate to the pad 31 but are not electrically connected to each other, as shown in FIG. 2b. In the preferred embodiment of the present invention, the means of circuit layout entails applying re-distribution technology to form from the conducting layer 30 the predetermined conducting wirings 33, also known as re-distribution layer (RDL) among persons skilled in the art.

Step C: disposing the die 40 at the pad 31 by a means of fixing, as shown in FIG. 2c, wherein the means of fixing is a die attach process.

Step D: connecting the die 40 electrically to the conducting wirings 33 by a means of electrical connection, as shown in FIG. 2d, wherein the means of electrical connection is a wire bonding process, and the wire 70 serves as an electrical conduction medium between the die 40 and the conducting wirings 33.

Step E: forming the encapsulant 50 for covering the die 40, the conducting wirings 33, and the wire 70, as shown in FIG. 2e, wherein the encapsulant 50 is formed by molding, so as to reduce the likelihood that the die 40 ruptures, the conducting wirings 33 develop an open circuit or shorted circuit, or the wire 70 severs, because of extrinsic factors.

Step F: forming a plurality of through holes 23 in the film layer 20 by a means of drilling, such that the conducting wirings 33 are exposed from the through holes 23, respectively, as shown in FIG. 2f, wherein the means of drilling is a laser drilling process.

Step G: providing a plurality of metal bumps 60 in the through holes 23, respectively, such that the metal bumps 60 are electrically connected to the conducting wirings 33, respectively, as shown in FIG. 2g, wherein the metal bumps 60 are formed in the through holes 23, respectively, by ball mounting, so as to enhance production quality and efficiency.

In conclusion, as compared to the prior art, the present invention provides the quad-flat non-lead package structure 10 and a method of packaging the quad-flat non-lead package structure 10, which feature structural simplicity and low packaging costs. Moreover, the metal bumps 60 are subject to structural restraints imposed by the through holes 23 and the conducting wirings 33 to therefore effectively reduce the effects of transverse acting force F1 and longitudinal acting force F2 on the quad-flat non-lead package structure 10; hence, even though various forces are applied to the quad-flat non-lead package structure 10, the metal bumps 60 are steadily and firmly fixed to the conducting wirings 33, thereby preventing pin disconnection and enhancing the adhesiveness required for surface-mount technology.

Constituent components disclosed in the embodiment of the present invention are illustrative rather than restrictive of the present invention. Replacement of the other equivalent components or changes thereto should fall within the claims of the present invention.

1. A method of packaging a quad-flat non-lead package structure, the method comprising the steps of:
providing an adhesive tape having a film layer and an adhesive disposed on the film layer;
providing a conducting layer on the adhesive;
forming a pad and a plurality of conducting wirings on the conducting layer by a means of circuit layout, wherein the conducting wirings are positioned proximate to the pad but are not electrically connected to each other;
providing a die, followed by disposing the die at the pad by a means of fixing;
connecting the die electrically to the conducting wirings by a means of electrical connection;
forming an encapsulant for covering the die and the conducting wirings;
forming a plurality of through holes in the adhesive tape by drilling, such that the conducting wirings are exposed from the through holes, respectively; and
providing a plurality of metal bumps in the through holes, respectively, in a manner to electrically connect the metal bumps to the conducting wirings, respectively.

2. (canceled)

3. The method of claim 1, wherein the means of fixing is a die attach process.

4. The method of claim 1, wherein the means of electrical connection is a wire bonding process.

5. The method of claim 1, wherein the means of drilling is a laser drilling process.

6. The method of claim 1, wherein the encapsulant is formed by molding.

7. A quad-flat non-lead package structure, comprising:
an adhesive tape having film layer, an adhesive disposed on the film layer and a plurality of through holes;
a conducting layer having a pad and a plurality of conducting wirings, wherein the pad and the conducting wirings are disposed at the adhesive but are not connected to each other, and the conducting wirings are disposed at the through holes, respectively;
a die fixedly disposed on the pad and electrically connected to the conducting wirings;
an encapsulant for covering the conducting layer and the die; and
a plurality of metal bumps disposed in the through holes, respectively, wherein the metal bumps each have an end electrically connected to a corresponding one of the conducting wirings and another end protruding from a corresponding one of the through holes.

8. The quad-flat non-lead package structure of claim 7, further comprising at least a wire electrically connecting the die and the conducting wirings.

9. The quad-flat non-lead package structure of claim 7, wherein the film layer has an adhesive, and the adhesive adheres the pad and the conducting wirings in place.
